(19) United States
(12) Patent Application Publication
(10) Pub. No.: US 2024/0014219 A1
(43) Pub. Date: Jan. 11, 2024

(54) DISPLAY PANEL, ARRAY SUBSTRATE AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen, Guan (CN)

(72) Inventor: Jing Liu, Shenzhen, Guangdong (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 17/618,421

(22) PCT Filed: Nov. 15, 2021
(86) PCT No.: PCT/CN2021/130679

§ 371 Date: Dec. 10, 2021

(30) Foreign Application Priority Data
Nov. 2, 2021 (CN) 202111290394.5

(51) Int. Cl. H01L 27/12; G02F 1/1362

(52) U.S. Cl. CPC H01L 27/124; G02F 1/136218; G02F 1/136295; G02F 1/136222; G02F 1/136209; H01L 27/1262

(57) ABSTRACT

A display panel, an array substrate, and a manufacturing method thereof are provided. The array substrate includes a data line, a first passivation layer, a shielding electrode, a second passivation layer, and a pixel electrode. The data line is disposed on a side of the substrate. The first passivation layer is disposed on the data line. The shielding electrode is disposed on a side of the first passivation layer away from the substrate. The second passivation layer is disposed on the shielding electrode. The pixel electrode is disposed on the second passivation layer. The shielding electrode is configured to shield an electric field between the data line and the pixel electrode, and an orthographic projection of a first side of the pixel electrode on the substrate at least partially overlaps an orthographic projection of the data line on the substrate.

### FIELD OF DISCLOSURE

The present disclosure relates to the field of display technologies, in particular to a display panel, an array substrate and a manufacturing method thereof.

### BACKGROUND

A traditional liquid crystal display panel includes an array substrate, a color filter substrate, and a liquid crystal layer disposed between the color filter substrate and the array substrate. Referring to FIG. 1, which shows a schematic diagram of an array substrate 10 of a display panel in the prior art. The array substrate 10 includes a data line 11, a gate line 12, a common electrode 13, a shielding electrode 14, a pixel electrode 15, and a thin film transistor 16. The data line 11 and the gate line 12 are perpendicular to each other and define a pixel region. The pixel electrode 15 and the thin film transistor 16 are disposed in the pixel area, and the pixel electrode 15 is electrically connected to the data line 11 and the gate line 12 through the thin film transistor 16.

Referring to FIG. 2, which shows a cross-sectional view of the array substrate 10 of FIG. 1 along a line A-A. The array substrate 10 also includes a base 17 and an insulating layer 18. The data line 11 and the common electrode 13 are disposed on the base 17. The insulating layer 18 is disposed on the base 17, the data line 11, and the common electrode 13. The shielding electrode 14 and the pixel electrode 15 are disposed on the insulating layer 18. The shielding electrode 14 adopts a DBS (data line black matrix less) technology, which disposing the shielding electrode 14 above the data line 11 to shield the data line 11, thereby replacing a traditional black matrix.

As shown in FIG. 2, in the traditional array substrate 10, in order to prevent the data line 11 from interfering with the pixel electrode 15 and causing adverse effects such as light leakage and crosstalk, it is necessary to disposed the common electrodes 13 on both sides of the data line 11, and disposed the shielding electrode 14 above the data line 11. However, the common electrodes 13 and shielding electrode 14 will cause a loss of an aperture of a pixel. Secondly, because the shielding electrode 14 is usually made of a transparent conductive material with a relatively large resistance, a potential recovery after being coupled by the data line 11 is slower, which is likely to cause a horizontal crosstalk. Furthermore, the common electrode 13 is usually made of an opaque metal material, and the common electrode 13 and the pixel electrode 15 form a storage capacitor. The storage capacitor is negatively correlated with the aperture of the pixel. In order to ensure the aperture of the pixel, a value of the storage capacitor is limited, which in turn causes a variable refresh rate (VRR) performance of the display panel to be poor. In addition, due to a limited range of the data line 11 that can be covered by the common electrode 13 and the shielding electrode 14, a coupling capacitance between the data line 11 and the pixel electrode 15 is relatively large, resulting in problems of capacitive crosstalk and vertical crosstalk.

Accordingly, it is necessary to provide an array substrate of a display panel to solve the problems existing in the prior art.

### Summary of Disclosure

In order to solve the above-mentioned problems in the prior art, a purpose of the present disclosure is to provide a display panel, an array substrate and a manufacturing method thereof, which can improve problems of aperture loss, crosstalk, and poor VRR.

To achieve the above purpose, the present disclosure provides an array substrate, including: a substrate; a data line disposed on one side of the substrate; a first passivation layer disposed on the data line; a shielding electrode disposed on a side of the first passivation layer away from the substrate; a second passivation layer disposed on the shielding electrode; and a pixel electrode disposed on the second passivation layer. The shielding electrode is configured to shield an electric field between the data line and the pixel electrode, and an orthographic projection of a first side of the pixel electrode on the substrate at least partially overlaps an orthographic projection of the data line on the substrate.

In some embodiment, the pixel electrode includes a second side, the second side is connected to the first side, and the array substrate further includes a common electrode disposed on the substrate and adjacent to the second side, and the shielding electrode is electrically connected to the common electrode through at least one through hole.

In some embodiment, an orthographic projection of the common electrode on the substrate only overlaps an orthographic projection of the second side of the pixel electrode on the substrate.

In some embodiment, the array substrate further includes a connection electrode. The connection electrode is disposed on the second passivation layer, and is configured to connect the shielding electrode and the common electrode through the at least one through hole.

In some embodiment, the array substrate further includes a red pixel, a green pixel, and a blue pixel. The connection electrode is arranged at the blue pixel.

In some embodiment, an orthographic projection of the pixel electrode on the substrate at least partially overlaps an orthographic projection of the shielding electrode on the substrate.

In some embodiment, the array substrate further includes a color filter layer disposed between the first passivation layer and the shielding electrode.

In some embodiment, a thickness of the second passivation layer is greater than or equal to 0.4 um.

The present disclosure also provides a manufacturing method of an array substrate, including: providing an substrate; disposing a data line on one a side of the substrate; disposing a first passivation layer on the data line; disposing a shielding electrode on a side of the first passivation layer away from the substrate; disposing a second passivation layer on the shielding electrode; and disposing a pixel electrode on the second passivation layer. The shielding electrode is configured to shield an electric field between the data line and the pixel electrode, and an orthographic projection of a first side of the pixel electrode on the substrate at least partially overlaps an orthographic projection of the data line on the substrate.

In some embodiment, before the data line is disposed on the side of the substrate, the manufacturing method further includes: disposing a common electrode on the substrate. When the pixel electrode is disposed on the second passivation layer, the manufacturing method further includes: arranging a second side of the pixel electrode to be adjacent to the common electrode. The second side is connected to the first side.

In some embodiment, before the shielding electrode is disposed on the side of the first passivation layer away from the substrate, the manufacturing method further includes: disposing a color filter layer on the first passivation layer. The color filter layer includes a red photoresist, a green photoresist, and a blue photoresist. After the second passivation layer is disposed on the shielding electrode, the manufacturing method further includes: forming two through holes exposing the shielding electrode and the common electrode in a setting region of the blue photoresist; and forming a connection electrode covering walls of the two through holes to electrically connect the shielding electrode and the common electrode.

In some embodiment, the pixel electrode and the connection electrode are formed by a same process, and the connection electrode is disposed on the second passivation layer and is spaced apart from the pixel electrode.

The present disclosure also provides a display panel, including: an array substrate, an opposite substrate, and a liquid crystal layer. The opposite substrate is opposite to the array substrate and includes: a second substrate; a black matrix layer disposed on the second substrate; and an opposite electrode disposed on the black matrix layer and the second substrate. The liquid crystal layer is disposed between the array substrate and the opposite substrate. The array substrate includes a first substrate; a data line disposed on a side of the first substrate; a first passivation layer disposed on the data line; a shielding electrode disposed on a side of the first passivation layer away from the first substrate; a second passivation layer disposed on the shielding electrode; and a pixel electrode disposed on the second passivation layer. The shielding electrode is configured to shield an electric field between the data line and the pixel electrode, and an orthographic projection of a first side of the pixel electrode on the first substrate at least partially overlaps an orthographic projection of the data line on the first substrate;

In some embodiment, the pixel electrode includes a second side, the second side is connected to the first side, and the array substrate further includes a common electrode disposed on the first substrate and adjacent to the second side, and the shielding electrode is electrically connected to the common electrode through at least one through hole.

In some embodiment, an orthographic projection of the common electrode on the first substrate only overlaps an orthographic projection of the second side of the pixel electrode on the first substrate.

In some embodiment, the array substrate further includes a connection electrode disposed on the second passivation layer and configured to connect the shielding electrode and the common electrode through the at least one through hole.

In some embodiment, the array substrate further includes a red pixel, a green pixel, and a blue pixel, and the connection electrode is arranged at the blue pixel.

In some embodiment, an orthographic projection of the pixel electrode on the first substrate at least partially overlaps an orthographic projection of the shielding electrode on the first substrate.

In some embodiment, the array substrate further includes a color filter layer disposed between the first passivation layer and the shielding electrode.

In some embodiment, the display panel includes a light-transmitting region and a non-light-transmitting region, and in the light-transmitting region, an orthographic projection of the pixel electrode on the first substrate is completely within an orthographic projection of the shielding electrode on the first substrate.

In comparison with the prior art, the present disclosure can shield the electric field between the data line and the pixel electrode by providing a shielding electrode between the data line and the pixel electrode, so that it is unnecessary to provide an opaque metal electrode between the data line and the pixel electrode, thereby effectively increasing an aperture of a display panel. Secondly, by disposing the shielding electrode, a coupling capacitance between the data line and the pixel electrode can be effectively reduced, thereby solving the problems of capacitance crosstalk and vertical crosstalk. Furthermore, by electrically connecting the shielding electrode and the common electrode to form a grid-like common electrode, a slower potential recovery caused by the data line is prevented, thereby solving the problem of horizontal crosstalk. In addition, because the shielding electrode is entirely disposed in a light-transmitting region of the display panel and has a large overlap area with the pixel electrode, it can effectively increase a storage capacitance, thereby solving negative issues caused by an increased pixel voltage drop in a VRR technology.

### BRIEF DESCRIPTION OF DRAWINGS

The following describes specific embodiments of the present disclosure in detail with reference to accompanying drawings to make technical solutions and other beneficial effects of the present disclosure obvious.

FIG. 1 shows a schematic diagram of an array substrate of a display panel in the prior art.

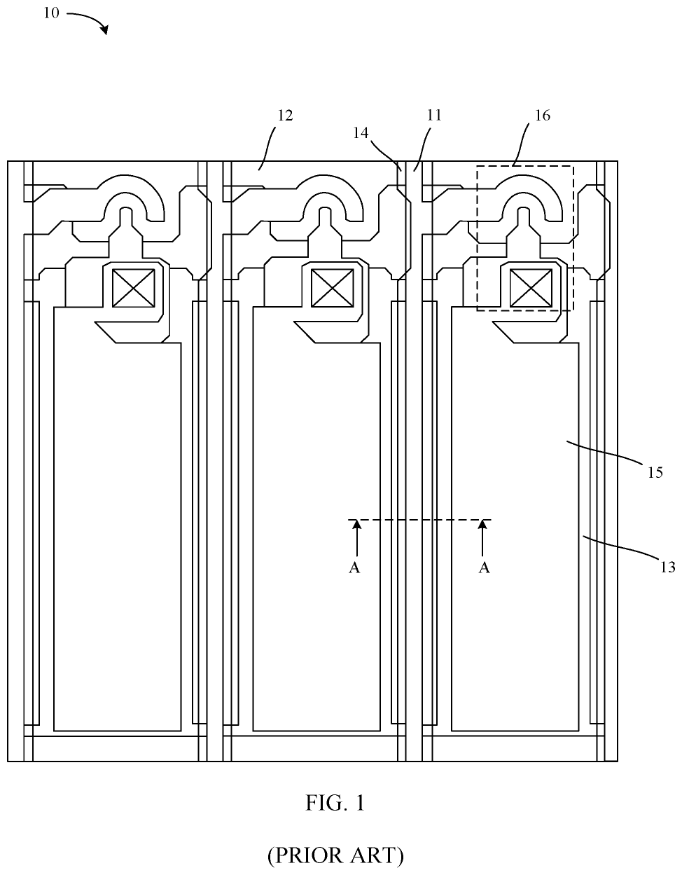

FIG. 2 shows a cross-sectional view of the array substrate of FIG. 1 along a line A-A.

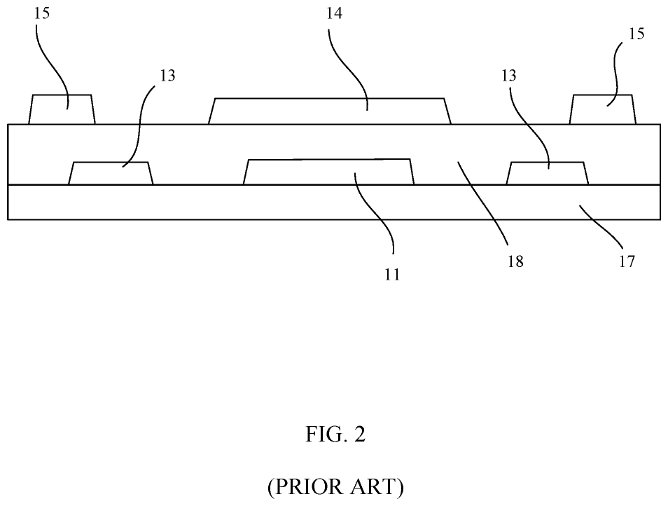

FIG. 3 shows a schematic diagram of a display panel according to an embodiment of the present disclosure.

FIG. 4 shows a top view of an array substrate of the display panel of FIG. 3.

FIG. 5 shows a cross-sectional view of the array substrate of FIG. 4 along a line B-B.

FIG. 6 is a flow chart showing a manufacturing method of an array substrate according to an embodiment of the present disclosure.

### DETAILED DESCRIPTION

The technical solutions in the embodiments of the present disclosure will be clearly and completely described below in conjunction with the drawings in the embodiments of the present disclosure. Apparently, the described embodiments are only a part of the embodiments of the present disclosure, but not all of the embodiments. Based on the embodiments in the present disclosure, all other embodiments obtained by those skilled in the art without creative efforts shall fall within the scope of protection of the present disclosure.

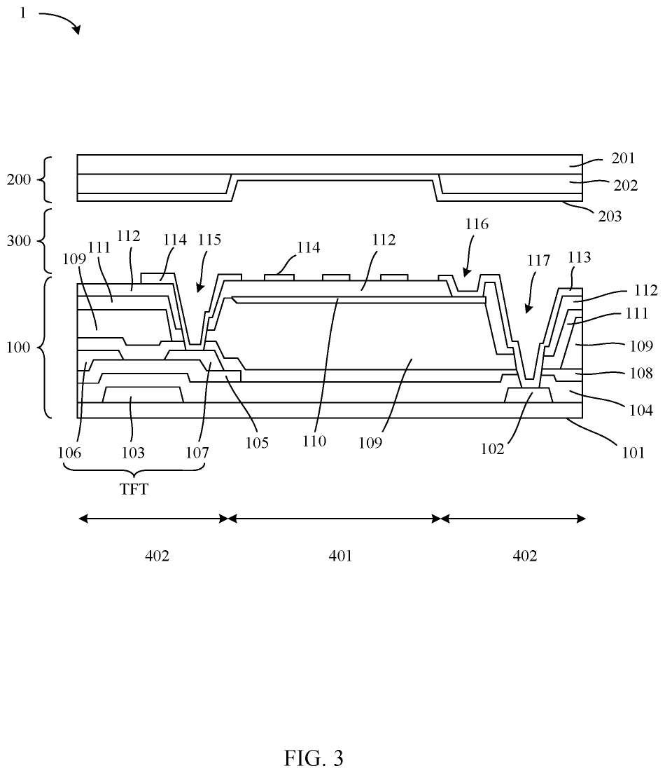

Please refer to FIG. 3, which shows a schematic diagram of a display panel 1 according to an embodiment of the present disclosure. The display panel 1 includes an array substrate 100, an opposite substrate 200, and a liquid crystal layer 300. The array substrate 100 and the opposite substrate 200 are arranged opposite to each other, and the liquid crystal layer 300 is disposed between the array substrate 100 and the opposite substrate 200. The display panel 1 includes a light-transmitting region 401 and a non-light-transmitting region 402.

As shown in FIG. 3, the array substrate 100 includes a first substrate 101, a common electrode 102, a gate 103, a gate insulating layer 104, a semiconductor layer 105, a source 106, a drain 107, a first passivation layer 108, a color filter layer 109, a shielding electrode 110, an isolation layer 111, a second passivation layer 112, a connection electrode 113, a pixel electrode 114, a first through hole 115, a second through hole 116, and a third through hole 117. The gate 103, the gate insulating layer 104, the semiconductor layer 105, the source 106, and the drain 107 constitute a thin film transistor TFT. The thin film transistor TFT is electrically insulated from the common electrode 102. The common electrode 102, the thin film transistor TFT, the first through hole 115, the second through hole 116, and the third through hole 117 are disposed in the non-light-transmitting region 402 of the display panel 1. In this embodiment, the shielding electrode 110 is made of a transparent conductive material (such as, indium tin oxide). A large portion of the shielding electrode 110 and the pixel electrode 114 is disposed in the light-transmitting region 401 of the display panel 1, and a small portion of the shielding electrode 110 and the pixel electrode 114 is disposed in the non-light-transmitting region 402.

As shown in FIG. 3, the opposite substrate 200 includes a second substrate 201, a black matrix layer 202, and an opposite electrode 203. The black matrix layer 202 is disposed on the second substrate 201. The opposite electrode 203 is disposed on the second substrate 201 and the black matrix layer 202. The black matrix layer 202 is disposed in the non-light-transmitting region 402 of the display panel 1. The opposite electrode 203 is entirely disposed in the light-transmitting region 401 and the non-light-transmitting region 402. By applying voltage to the pixel electrode 114 of the array substrate 100 and the opposite electrode 203 of the opposite substrate 200 to generate an electric field on the liquid crystal layer 300, a direction of liquid crystal molecules of the liquid crystal layer 300 and a polarization of incident light can be controlled, so that the display panel 1 can display an image.

As shown in FIG. 3, the common electrode 102 and the gate 103 are disposed on the first substrate 101. The gate insulating layer 104 is disposed on the gate 103 and includes an opening exposing a surface of the common electrode 102 away from the first substrate 101. The semiconductor layer 105 is disposed on the gate insulating layer 104 and corresponding to the gate 103. The source 106 and the drain 107 are disposed on the semiconductor layer 105. The first passivation layer 108 is disposed on a side of the common electrode 102 and the thin film transistor TFT away from the first substrate. Specifically, the first passivation layer 108 is disposed on the gate insulating layer 104, the semiconductor layer 105, the source 106, and the drain 107. The first passivation layer 108 includes an opening that exposes the surface of the common electrode 102 away from the first substrate 101 and an opening that exposes a surface of the drain 107 of the thin film transistor TFT away from the first substrate 101. The color filter layer 109 is disposed on the first passivation layer 108. The color filter layer 109 includes an opening that exposes the surface of the common electrode 102 away from the first substrate 101 and an opening that exposes the surface of the drain 107 of the thin film transistor TFT away from the first substrate 101. The shielding electrode 110 is disposed on a side of the first passivation layer 108 away from the first substrate 101. Specifically, the shielding electrode 110 is disposed on the color filter layer 109. The isolating layer 111 is disposed on a surface of the color filter layer 109 that is not covered by the shielding electrode 110. The isolating layer 111 includes an opening that exposes the surface of the common electrode 102 away from the first substrate 101 and includes an opening that exposes the drain 107 of the thin film transistor TFT away from the surface of the first substrate 101. The second passivation layer 112 is disposed on the isolating layer 111 and the shielding electrode 110. The second passivation layer 112 includes an opening that exposes the surface of the common electrode 102 away from the first substrate 101, an opening that exposes the drain 107 of the thin film transistor TFT away from the first substrate 101, and an opening that exposes a part of a surface of the shielding electrode 110 away from the first substrate 101. It should be understood that since the shielding electrode 110 is disposed on the color filter layer 109 and the second passivation layer 112, there is no need to provide an additional insulating layer to prevent the shielding electrode 110 from contacting other conductive layers.

As shown in FIG. 3, the openings of the first passivation layer 108, the color filter layer 109, the isolating layer 111 and the second passivation layer 112 exposing the drain 107 of the thin film transistor TFT constitute the first through hole 115. The opening of the second passivation layer 112 that exposes the shielding electrode 110 is the second through hole 116. That is, the second through hole 116 extends through the second passivation layer 112 to expose the shielding electrode 110. The openings of the gate insulating layer 104, the first passivation layer 108, the color filter layer 109, the isolating layer 111, and the second passivation layer 112 exposing the common electrode 102 constitute the third through hole 117. That is, the third through hole 117 extends through the gate insulating layer 104, the first passivation layer 108, the color filter layer 109, the isolating layer 111, and the second passivation layer 112 to expose the common electrode 102.

As shown in FIG. 3, the pixel electrode 114 is disposed on the second passivation layer 112 and covers a wall of the first through hole 115. That is, the pixel electrode 114 is electrically connected to the drain 107 of the thin film transistor TFT through the first through hole 115. The connection electrode 113 is disposed on the second passivation layer 112 and is spaced apart from the pixel electrode 114. The connection electrode 113 covers walls of the second through hole 116 and the third through hole 117. That is, the connection electrode 113 is configured to electrically connect the shielding electrode 110 and the common electrode 102 through the second through hole 116 and the third through hole 117. In this embodiment, by electrically connecting the shielding electrode 110 and the common electrode 102 to form a grid-like common electrode, it is possible to prevent the slower potential recovery caused by the data line, thereby solving the problem of horizontal crosstalk.

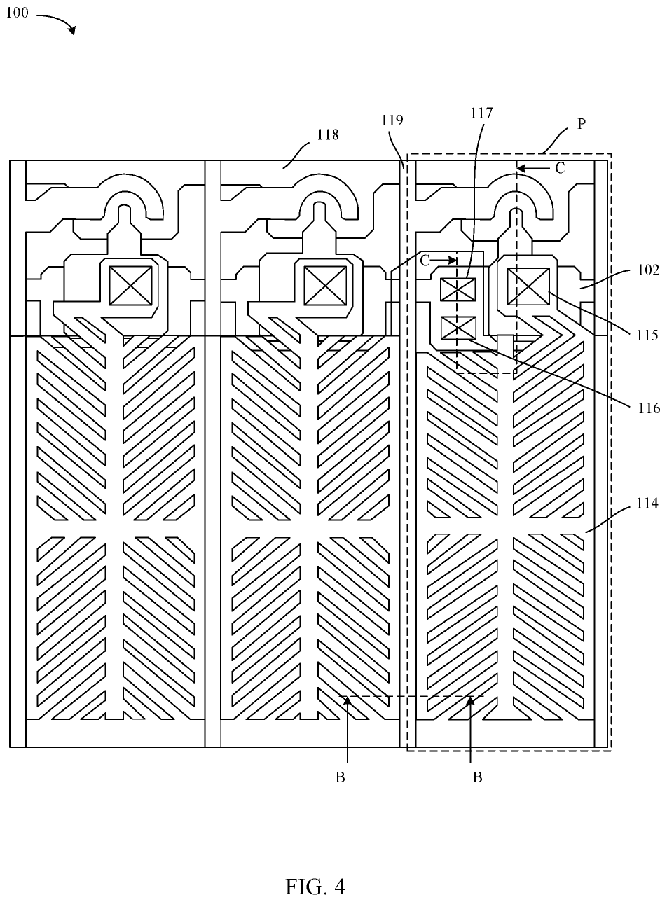

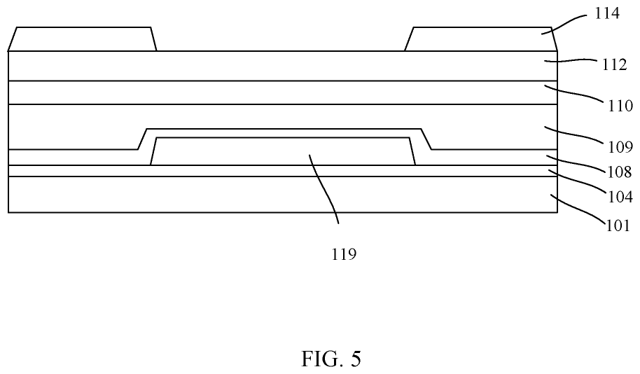

Referring to FIG. 4 and FIG. 5, FIG. 4 shows a top view of the array substrate 100 of the display panel 1 in FIG. 3. FIG. 5 shows a cross-sectional view of the array substrate of FIG. 4 along a line B-B. The schematic diagram of the array substrate 100 in FIG. 3 is equivalent to a cross-sectional view of the array substrate 100 in FIG. 4 along a line C-C. As shown in FIG. 4, the array substrate 100 includes a plurality of gate lines 118 and a plurality of data lines 119, and the gate lines 118 and the data lines 119 define a plurality of pixels P. The gate line 118 and the common electrode 102 extend along a first direction, and the data line 119 extends along a second direction, where the first direction is perpendicular to the second direction. The pixel electrode 114 of each pixel P includes a first side, a second side, and a third side. The first side is opposite to the third side, and the second side connects the first side and the third side. The first side and the third side of the pixel electrode 114 are adjacent to two data lines 119, and the second side of the pixel electrode 114 is adjacent to the common electrode 102. In this embodiment, as shown in FIG. 4, when viewed from a top view, the common electrode 102 is only adjacent to the second side of the pixel electrode 114, and does not extend to the first side and the third side adjacent to the data line 119. Therefore, an orthographic projection of the common electrode 102 on the first substrate 101 only overlaps with an orthographic projection of the second side of the pixel electrode 114 on the first substrate 101.

As shown in FIG. 5, an orthographic projection of the first side of the pixel electrode 114 on the first substrate 101 at least partially overlaps an orthographic projection of the data line 119 on the first substrate 101. It should be understood that the shielding electrode 110 can shield the electric field between the data line 119 and the pixel electrode 114. Therefore, it is not necessary to provide an opaque metal electrode between the data line 119 and the pixel electrode 114, so that the pixel electrode 114 can be extended to the adjacent data line 119, which can effectively increase the aperture of the display panel. Furthermore, by disposing the shielding electrode 110 between the data line 119 and the pixel electrode 114, a coupling capacitance between the data line 119 and the pixel electrode 114 can be effectively reduced, thereby solving the problems of capacitive crosstalk and vertical crosstalk.

As shown in FIG. 4, each pixel is connected to a single gate line and a single data line, and contains the thin film transistor TFT and a storage capacitor to drive the pixel. As shown in FIG. 3, an orthographic projection of the pixel electrode 114 on the first substrate 101 at least partially overlaps an orthographic projection of the shielding electrode 110 on the first substrate 101. Therefore, the pixel electrode 114 and the shielding electrode 110 together form the storage capacitor of the pixel. It should be understood that in a driving operation of the display panel 1, in order to avoid an increase in power consumption, a variable refresh rate (VRR) technology may be used. According to the VRR technology, by adding a storage capacitor, it is possible to effectively avoid an increased pixel voltage drop when driving the display panel at a low frequency of 60 Hz or lower, resulting in defects such as flicker and image retention. In this embodiment, since the shielding electrode 110 is entirely disposed in the light-transmitting region of the display panel 1 and has a large overlap area with the pixel electrode 114, the storage capacitance can be effectively increased. Specifically, as shown in FIG. 3, in the light-transmitting region 401 of the display panel 1, the orthographic projection of the pixel electrode 114 on the first substrate 101 is completely within the orthographic projection of the shielding electrode 110 on the first substrate 101. Therefore, the present disclosure can solve the negative problems caused by the increase in pixel voltage drop in the VRR technology. In addition, through the entire shielding electrode 110, the capacitance crosstalk and vertical crosstalk problems caused by a position shift in a process can be prevented.

As shown in FIG. 3 and FIG. 4, a value of the storage capacitor can be further adjusted by adjusting a thickness of the second passivation layer 112 between the pixel electrode 114 and the shielding electrode 110. The smaller the thickness of the second passivation layer 112, the larger the value of the storage capacitor. However, if the thickness of the second passivation layer 112 is too thin, which may easily lead to process risks or insufficient charging rate risks. Therefore, in some embodiments, the thickness of the second passivation layer 112 is preferably greater than or equal to 0.4 um.

It should be understood that the data line 119 is formed simultaneously with the source 106 and the drain 107 of the thin film transistor TFT. Therefore, as shown in FIG. 3 and FIG. 4, the color filter layer 109 with a relatively thick thickness is spaced between the data line 119 and the shielding electrode 110, so that no additional parasitic capacitance is generated between the data line 119 and the shielding electrode 110.

As shown in FIG. 3 and FIG. 4, the color filter layer 109 corresponding to different pixels P includes the same or different color photoresists, such as red photoresists, green photoresists, and blue photoresists. In other words, the pixels P of the array substrate 100 of this embodiment include red pixels, green pixels, and blue pixels. In some embodiments, the second through hole 116, the third through hole 117, and the connection electrode 113 are disposed in the blue pixel, that is, a setting region of the blue photoresist. The arrangement of the second through hole 116, the third through hole 117, and the connection electrode 113 will cause the pixel to lose a part of the aperture. In comparison with changing the aperture of other color pixels, choosing to reduce the aperture of the blue pixel can minimize an influence on a light transmittance in terms of visual perception. In some embodiments, in each pixel including the second through hole 116 and the third through hole 117, the through hole has the same shape, size, and layout, so that the problem of color unevenness (mura) can be prevented.

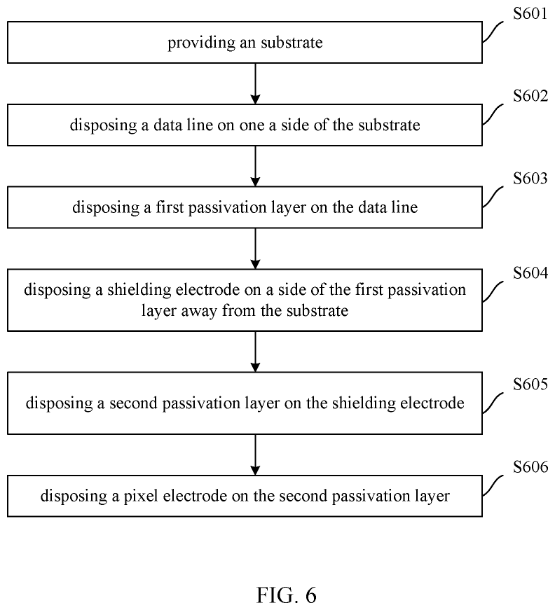

FIG. 6 is a flow chart showing a manufacturing method of an array substrate according to an embodiment of the present disclosure. The manufacturing method of FIG. 6 is used to manufacture the aforementioned array substrate 100. The manufacturing method of the array substrate 100 includes the following steps.

In a step S601, a substrate is provided. Specifically, the first substrate 101 of the array substrate 100 is provided.

In a step S602, the data line 119 is disposed on a side of the first substrate 101. Specifically, first, a first metal layer is disposed on the first substrate 101, and the common electrode 102, the gate line 118, and the gate 103 of the thin film transistor TFT are formed through an etching process. Next, a gate insulating layer 104 is formed on the common electrode 102, the gate line 118, and the gate 103. The gate insulating layer 104 includes an opening exposing a surface of the common electrode 102 away from the first substrate 101. The semiconductor layer 105 is disposed on the gate insulating layer 104. The semiconductor layer 105 is arranged corresponding to the gate 103. After that, a second metal layer is disposed on the gate insulating layer 104 and the semiconductor layer 105, and the data line 119 and the source 106 and the drain 107 of the thin film transistor TFT are formed through an etching process.

In a step S603, the first passivation layer 108 is disposed on the data line 119. The first passivation layer 108 is also disposed on the gate insulating layer 104, the semiconductor layer 105, the source 106, and the drain 107. The first passivation layer 108 includes an opening that exposes the surface of the common electrode 102 away from the first substrate 101 and an opening that exposes a surface of the drain 107 of the thin film transistor TFT away from the first substrate 101.

In a step S604, the shielding electrode 110 is disposed on a side of the first passivation layer 108 away from the first substrate 101. Specifically, the color filter layer 109 is disposed on the first passivation layer 108. The color filter layer 109 includes the red photoresists, the green photoresists, and the blue photoresists. The color filter layer 109 includes an opening that exposes the surface of the drain 107 of the thin film transistor TFT away from the first substrate 101. In addition, in the setting region of the blue photoresist, the color filter layer 109 also includes an opening that exposes a surface of the common electrode 102 away from the first substrate 101. Next, the shielding electrode 110 is disposed on the color filter layer 109.

In a step S605, the second passivation layers 112 is disposed on the shielding electrode 110. Specifically, the isolating layer 111 is disposed on a surface of the color filter layer 109 that is not covered by the shielding electrode 110. The isolating layer 111 includes an opening exposing the surface of the drain 107 of the thin film transistor TFT away from the first substrate 101. In addition, in the setting region of the blue photoresist, the isolating layer 111 includes an opening that exposes the surface of the common electrode 102 away from the first substrate 101. The second passivation layer 112 is disposed on the isolating layer 111 and shielding electrode 110. The second passivation layer 112 includes an opening that exposes the surface of the drain 107 of the thin film transistor TFT away from the first substrate 101. In addition, in the setting region of the blue photoresist, the second passivation layer 112 includes an opening that exposes the surface of the common electrode 102 away from the first substrate 101 and an opening that exposes a part of the surface of the shielding electrode 110 away from the first substrate 101.

As shown in FIG. 3, the openings of the first passivation layer 108, the color filter layer 109, the isolating layer 111, and the second passivation layer 112 exposing the drain 107 of the thin film transistor TFT constitute the first through hole 115. In the setting region of the blue photoresist, the array substrate 100 is also formed with the second through hole 116 and the third through hole 117. Specifically, the opening of the second passivation layer 112 that exposes the shielding electrode 110 is the second through hole 116. That is, the second through hole 116 extends through the second passivation layer 112 to expose the shielding electrode 110. The openings of the gate insulating layer 104, the first passivation layer 108, the color filter layer 109, the isolating layer 111, and the second passivation layer 112 exposing the common electrode 102 constitute the third through hole 117. That is, the third through hole 117 extends through the gate insulating layer 104, the first passivation layer 108, the color filter layer 109, the isolating layer 111, and the second passivation layer 112 to expose the common electrode 102.

In a step S606, the pixel electrode 114 is disposed on the second passivation layer 112, where the pixel electrode 114 includes the first side and the second side, and the second side is connected to the first side. When disposing the pixel electrode 114 on the second passivation layer 112, the second side of the pixel electrode 114 is arranged to be adjacent to the common electrode 102. The shielding electrode 110 is configured to shield the electric field between the data line 119 and the pixel electrode 114, and the orthographic projection of the first side of the pixel electrode 114 on the first substrate 101 at least partially overlaps the orthographic projection of the data line 119 on the first substrate 101. Next, the connection electrode 113 is disposed on the second passivation layer 112 to form the array substrate 100. The pixel electrode 114 is disposed on the second passivation layer 112 and covers a wall of the first through hole 115 to be electrically connected to the drain 107 of the thin film transistor TFT. In some embodiments, the pixel electrode 114 and the connection electrode 113 can be formed by the same process. The connection electrode 113 is disposed on the second passivation layer 112 and is spaced apart from the pixel electrode 114. The connection electrode 113 covers the walls of the second through hole 116 and the third through hole 117, so that the shielding electrode 110 and the common electrode 102 are electrically connected through the connection electrode 113. It should be understood that the features and functions of the array substrate manufactured by this embodiment are similar to those of the aforementioned array substrate 100, and will not be repeated here.

In summary, the present disclosure can shield the electric field between the data line and the pixel electrode by providing the shielding electrode between the data line and the pixel electrode, so that it is unnecessary to provide an opaque metal electrode between the data line and the pixel electrode, thereby effectively increasing an aperture of a display panel. Secondly, by disposing the shielding electrode, a coupling capacitance between the data line and the pixel electrode can be effectively reduced, thereby solving the problems of capacitance crosstalk and vertical crosstalk. Furthermore, by electrically connecting the shielding electrode and the common electrode to form a grid-like common electrode, a slower potential recovery caused by the data line is prevented, thereby solving the problem of horizontal crosstalk. In addition, because the shielding electrode is entirely disposed in a light-transmitting region of the display panel and has a large overlap area with the pixel electrode, it can effectively increase a storage capacitance, thereby solving negative issues caused by an increased pixel voltage drop in a VRR technology.

The above describes in detail the display panel, the array substrate, and the manufacturing method of the embodiments of the present disclosure. Specific examples are used in this specification to illustrate principles and implementations of the present disclosure. The description of the above embodiments is only used to help understand the technical solutions of the present disclosure and its core idea. Those of ordinary skill in the art should understand that they can still modify the technical solutions described in the foregoing embodiments, or equivalently replace some of the technical features. However, these modifications or replacements do not cause the essence of the corresponding technical solutions to deviate from the scope of the technical solutions of the embodiments of the present disclosure.

What is claimed is:

1. An array substrate, comprising:
a substrate;
a data line disposed on one side of the substrate;
a first passivation layer disposed on the data line;
a shielding electrode disposed on a side of the first passivation layer away from the substrate;
a second passivation layer disposed on the shielding electrode; and
a pixel electrode disposed on the second passivation layer, wherein the shielding electrode is configured to shield an electric field between the data line and the pixel electrode, and an orthographic projection of a first side of the pixel electrode on the substrate at least partially overlaps an orthographic projection of the data line on the substrate.

2. The array substrate according to claim 1, wherein the pixel electrode comprises a second side, the second side is connected to the first side, and the array substrate further comprises a common electrode disposed on the substrate and adjacent to the second side, and the shielding electrode is electrically connected to the common electrode through at least one through hole.

3. The array substrate according to claim 2, wherein an orthographic projection of the common electrode on the substrate only overlaps an orthographic projection of the second side of the pixel electrode on the substrate.

4. The array substrate according to claim 2, further comprising a connection electrode, wherein the connection electrode is disposed on the second passivation layer, and is configured to connect the shielding electrode and the common electrode through the at least one through hole.

5. The array substrate according to claim 4, further comprising a red pixel, a green pixel, and a blue pixel, wherein the connection electrode is arranged at the blue pixel.

6. The array substrate according to claim 1, wherein an orthographic projection of the pixel electrode on the substrate at least partially overlaps an orthographic projection of the shielding electrode on the substrate.

7. The array substrate according to claim 1, further comprising a color filter layer disposed between the first passivation layer and the shielding electrode.

8. The array substrate according to claim 1, wherein a thickness of the second passivation layer is greater than or equal to 0.4 um.

9. A manufacturing method of an array substrate, comprising:
providing an substrate;
disposing a data line on one a side of the substrate;
disposing a first passivation layer on the data line;
disposing a shielding electrode on a side of the first passivation layer away from the substrate;
disposing a second passivation layer on the shielding electrode; and
disposing a pixel electrode on the second passivation layer, wherein the shielding electrode is configured to shield an electric field between the data line and the pixel electrode, and an orthographic projection of a first side of the pixel electrode on the substrate at least partially overlaps an orthographic projection of the data line on the substrate.

10. The manufacturing method of the array substrate according to claim 9, wherein before the data line is disposed on the side of the substrate, the manufacturing method further comprises:
disposing a common electrode on the substrate; and
when the pixel electrode is disposed on the second passivation layer, the manufacturing method further comprises: arranging a second side of the pixel electrode to be adjacent to the common electrode, wherein the second side is connected to the first side.

11. The manufacturing method of the array substrate according to claim 10, wherein before the shielding electrode is disposed on the side of the first passivation layer away from the substrate, the manufacturing method further comprises: disposing a color filter layer on the first passivation layer, wherein the color filter layer comprises a red photoresist, a green photoresist, and a blue photoresist;
after the second passivation layer is disposed on the shielding electrode, the manufacturing method further comprises:
forming two through holes exposing the shielding electrode and the common electrode in a setting region of the blue photoresist; and
forming a connection electrode covering walls of the two through holes to electrically connect the shielding electrode and the common electrode.

12. The manufacturing method of the array substrate according to claim 11, wherein the pixel electrode and the connection electrode are formed by a same process, and the connection electrode is disposed on the second passivation layer and is spaced apart from the pixel electrode.

13. A display panel, comprising:
an array substrate, comprising:
a first substrate;
a data line disposed on a side of the first substrate;
a first passivation layer disposed on the data line;
a shielding electrode disposed on a side of the first passivation layer away from the first substrate;
a second passivation layer disposed on the shielding electrode; and
a pixel electrode disposed on the second passivation layer, wherein the shielding electrode is configured to shield an electric field between the data line and the pixel electrode, and an orthographic projection of a first side of the pixel electrode on the first substrate at least partially overlaps an orthographic projection of the data line on the first substrate;
an opposite substrate opposite to the array substrate, comprising:
a second substrate;
a black matrix layer disposed on the second substrate; and
an opposite electrode disposed on the black matrix layer and the second substrate; and
a liquid crystal layer disposed between the array substrate and the opposite substrate.

14. The display panel according to claim 13, wherein the pixel electrode comprises a second side, the second side is connected to the first side, and the array substrate further comprises a common electrode disposed on the first substrate and adjacent to the second side, and the shielding electrode is electrically connected to the common electrode through at least one through hole.

15. The display panel according to claim 14, wherein an orthographic projection of the common electrode on the first substrate only overlaps an orthographic projection of the second side of the pixel electrode on the first substrate.

16. The display panel according to claim 14, wherein the array substrate further comprises a connection electrode disposed on the second passivation layer and configured to connect the shielding electrode and the common electrode through the at least one through hole.

17. The display panel according to claim 16, wherein the array substrate further comprises a red pixel, a green pixel, and a blue pixel, and the connection electrode is arranged at the blue pixel.

18. The display panel according to claim 13, wherein an orthographic projection of the pixel electrode on the first substrate at least partially overlaps an orthographic projection of the shielding electrode on the first substrate.

19. The display panel according to claim 13, wherein the array substrate further comprises a color filter layer disposed between the first passivation layer and the shielding electrode.

20. The display panel according to claim 13, wherein the display panel comprises a light-transmitting region and a non-light-transmitting region, and in the light-transmitting region, an orthographic projection of the pixel electrode on the first substrate is completely within an orthographic projection of the shielding electrode on the first substrate.
